(19) United States
(12) Patent Application Publication
(10) Pub. No.: US 2018/0241387 A1
(43) Pub. Date: Aug. 23, 2018

(54) DRAIN LAG COMPENSATION CIRCUIT FOR RF POWER TRANSISTORS

(71) Applicant: MACOM Technology Solutions Holdings, Inc., Lowell, MA (US)

(72) Inventor: Jonathan Leckey, Newry (GB)

(73) Assignee: MACOM Technology Solutions Holdings, Inc., Lowell, MA (US)

(21) Appl. No.: 15/438,971

(22) Filed: Feb. 22, 2017

(51) Int. Cl. H03K 17/16; H03F 1/56; H03F 3/45; H03F 3/21; H03F 3/193

(52) U.S. Cl. CPC H03K 17/161; H03F 1/56; H03F 3/45; H03F 2200/387; H03F 3/193; H03F 2200/451; H03F 2200/222; H03F 3/21

(57) ABSTRACT

A transistor circuit includes a main transistor having a gate terminal, a drain terminal and a source terminal, and a drain lag compensation circuit configured to sense a drain voltage on the drain terminal of the main transistor and to control a drain current through the main transistor based on the sensed drain voltage. The drain lag compensation circuit may include a reference transistor having a drain terminal coupled to a drain terminal of the main transistor, and a sensing circuit that is coupled to a source terminal of the reference transistor and provides a control voltage to a gate terminal of the main transistor. The reference transistor may be thermally coupled to the main transistor. The main transistor may be a GaN RF power transistor.

### BACKGROUND

### Technical Field

The disclosed technology relates to transistor circuits and, more particularly, to drain lag compensation circuits for RF (radio frequency) power transistors.

### Discussion of Related Art

Gallium nitride transistors are used for radio frequency power amplifiers because they can operate at high temperatures and high voltage. Such devices may be used, for example, in the base station of a mobile phone system to output modulated signals.

A mechanism that limits the performance of gallium nitride transistors is the trapping effect which causes a reduction in drain current after the application of a high voltage. This mechanism is described by Joh et al. in “A Current-Transient Methodology For Trap Analysis For GaN High Electron Mobility Transistors”, IEEE Transactions on Electron Devices, Vol. 58, No. 1, January 2011, pages 132-140. The trapping effect, also known as the drain lag effect, may change the characteristics of the transistor when a high amplitude pulse is applied. The effect changes with time and may cause distortion in the output signal.

It has been proposed to utilize digital pre-distortion to compensate for the drain lag effect. However, it is difficult to track changes in transistor characteristics using the digital pre-distortion technique.

Accordingly, there is a need for circuits and methods for partially or entirely overcoming the drain lag effect in transistors.

### SUMMARY

The disclosed technology provides a compensation circuit for at least partially compensating for the drain lag effect in transistors. The compensation circuit senses a drain voltage on the drain terminal of a main transistor and controls a drain current through the main transistor based on the sensed drain voltage. The compensation circuit utilizes a reference transistor which may be thermally coupled to the main transistor and, in some embodiments, may be on the same substrate with the main transistor. By controlling the drain current through the main transistor, the drain lag effect is effectively compensated. The main transistor may be a gallium nitride RF power transistor, but this is not a limitation.

In accordance with embodiments, a transistor circuit comprises a main transistor having a gate terminal, a drain terminal and a source terminal, and a drain lag compensation circuit configured to sense a drain voltage on the drain terminal of the main transistor and to control a drain current through the main transistor based on the sensed drain voltage.

In some embodiments, the main transistor comprises a gallium nitride RF power transistor.

In some embodiments, the drain lag compensation circuit comprises a reference transistor having a drain terminal coupled to the drain terminal of the main transistor and having a source terminal coupled through a first resistor to ground, and a sensing circuit having a first input coupled to the source terminal of the reference transistor, a second input that receives a reference value and an output coupled to the gate terminal of the main transistor and to the gate terminal of the reference transistor.

In some embodiments, the reference transistor is thermally coupled to the main transistor.

In some embodiments, the sensing circuit is configured to compare the voltage on the source terminal of the reference transistor with the reference value and to provide a compensation voltage to the gate terminals of the main transistor and the reference transistor based on the comparison.

In some embodiments, the drain lag compensation circuit is configured to control the main transistor to maintain a constant quiescent drain current through the main transistor.

In accordance with embodiments, a method for operating a main transistor comprises sensing a drain voltage on a drain terminal of the main transistor, and controlling a drain current through the main transistor based on the sensed drain voltage.

In some embodiments, sensing the drain voltage on the drain terminal of the main transistor is performed by a reference transistor having a drain terminal coupled to the drain terminal of the main transistor.

In some embodiments, controlling the main transistor comprises comparing a value representative of the sensed drain voltage with a reference value and providing a compensation value to a gate terminal of the main transistor based on the comparison.

In some embodiments, the method further comprises adjusting the reference value to thereby adjust the current through the main transistor.

In some embodiments, controlling the drain current comprises maintaining a constant quiescent drain current through the main transistor.

In accordance with embodiments, a transistor circuit comprises a main transistor having a gate terminal, a drain terminal and a source terminal; a reference transistor having a drain terminal coupled to the drain terminal of the main transistor and having a source terminal coupled through a first resistor to ground; and a sensing circuit having a first input coupled to the source terminal of the reference transistor, a second input that receives a reference value, and an output coupled to gate terminal of the main transistor and to a gate terminal of the reference transistor.

In some embodiments, the transistor circuit further comprises a second resistor coupled between the output of the sensing circuit and the gate terminal of the main transistor and a third resistor coupled between the output of the sensing circuit and the gate terminal of the reference transistor.

In some embodiments, the sensing circuit comprises an operational amplifier, the first input of the sensing circuit comprises a non-inverting input of the operational amplifier and the second input of the sensing circuit comprises an inverting input of the operational amplifier.

In some embodiments, the main transistor and the reference transistor are fabricated on a single substrate.

### BRIEF DESCRIPTION OF DRAWINGS

The disclosed technology may be understood with reference to the accompanying drawings, which are incorporated herein by reference and in which:

FIG. 1 is a simplified schematic block diagram of a transistor circuit in accordance with embodiments;

FIG. 2 is a schematic diagram of a transistor circuit in accordance with embodiments; and

FIG. 3 is a simplified cross-sectional diagram of a semiconductor device including a main transistor and a reference transistor formed on a substrate.

### DETAILED DESCRIPTION

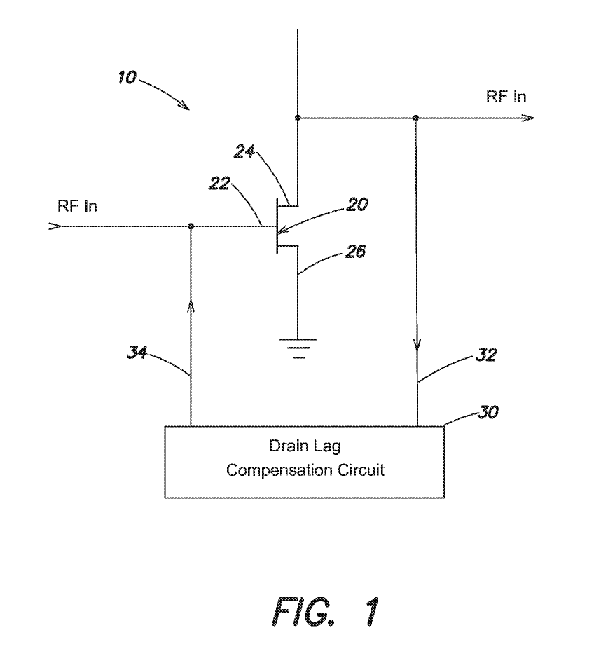

A schematic block diagram of a transistor circuit in accordance with embodiments is shown in FIG. 1. A transistor circuit 10 includes a transistor 20 and a drain lag compensation circuit 30. The transistor 20, referred to herein as a main transistor, is a component of an operating circuit, such as for example a power amplifier. Other components of the operating circuit are omitted for simplicity of illustration. Bias circuits and matching circuits are also omitted for simplicity of illustration. In some embodiments, the transistor 20 may be a gallium nitride (GaN) high electron mobility transistor (HEMT). However, transistor circuit 10 is not limited to gallium nitride HEMTs.

As shown, the transistor 20 includes a gate terminal 22, a drain terminal 24 and a source terminal 26. The source terminal 26 is connected to ground in the embodiment of FIG. 1. During operation, the transistor 20 receives an RF input signal on the gate terminal 22 and provides an RF output signal on the drain terminal 24.

The drain lag compensation circuit 30 includes an input 32 coupled, either directly or through one or more additional components (not shown in FIG. 1), to the drain terminal 24 of transistor 20 and an output 34 coupled, either directly or through one or more additional components (not shown in FIG. 1), to the gate terminal 22 of transistor 20. The drain lag compensation circuit 30 senses a drain voltage on drain terminal 24 of transistor 20 and provides a compensation voltage to gate terminal 22 of transistor 20.

The compensation voltage applied to gate terminal 22 by the drain lag compensation circuit 30 controls a drain current through transistor 20 based on the sensed drain voltage. In particular, the drain lag compensation circuit 30 controls the drain current through transistor 20 by maintaining a constant quiescent drain current through transistor 20. The term “quiescent current”, sometimes referred to as “bias current”, refers to the current through transistor 20 in the absence of an RF input signal or other input signal. The drain lag compensation circuit 30 also controls the drain current through transistor 20 in the presence of an RF input signal or other input signal to compensate for the drain lag effect.

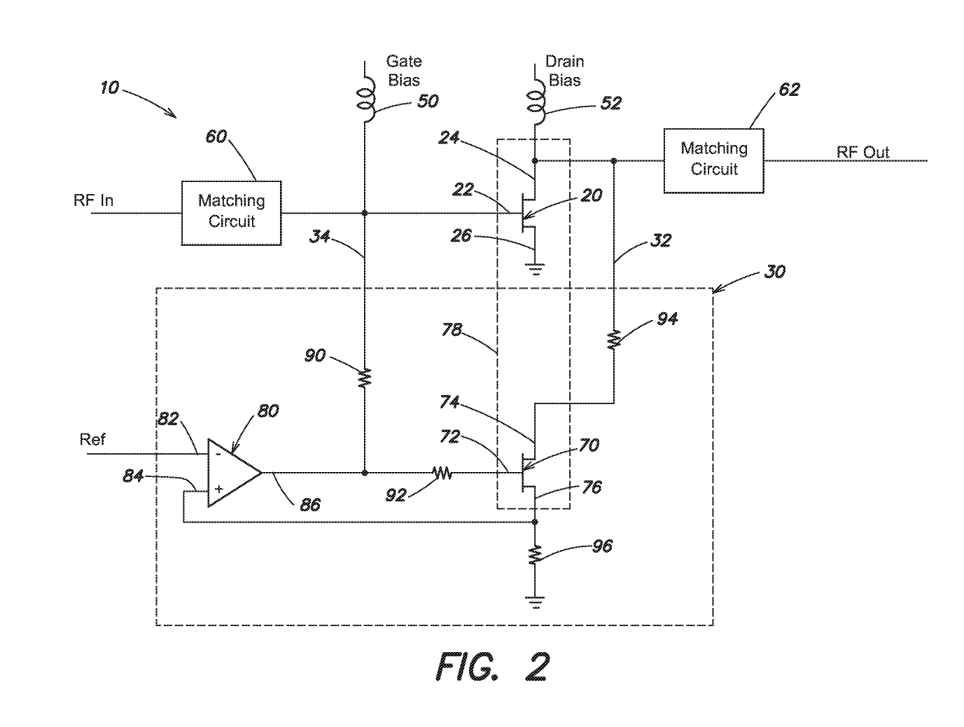

A schematic diagram of transistor circuit 10 in accordance with embodiments is shown in FIG. 2. Like elements in FIGS. 1 and 2 have the same reference numerals.

In the embodiment of FIG. 2, a gate bias voltage is applied to gate terminal 22 of transistor 20 through a choke inductor 50 and a drain bias voltage is applied to drain terminal 24 of transistor 20 through a choke inductor 52. The RF input is applied to gate terminal 22 of transistor 20 through an input matching circuit 60 and the RF output of transistor 20 is coupled from drain terminal 24 through an output matching circuit 62 to the RF output.

In the embodiment of FIG. 2, the drain lag compensation circuit 30 includes a reference transistor 70 and a sensing circuit 80 which, in the embodiment of FIG. 2, may be an operational amplifier. The reference transistor 70 includes a gate terminal 72, a drain terminal 74 and a source terminal 76. The reference transistor 70 may be the same type as main transistor 20 such that main transistor 20 and reference transistor 70 have similar characteristics, except that reference transistor 70 is not required to operate at high power levels. Thus, reference transistor 70 may be a scaled-down version of main transistor 20.

In addition, the reference transistor 70 may be thermally coupled to the main transistor, as indicated by dashed line 78 in FIG. 2. Thermal coupling may be achieved, for example, by fabricating main transistor 20 and reference transistor 70 on the same semiconductor substrate, such that main transistor 20 and reference transistor 70 have approximately the same temperature during operation. As discussed below, the drain lag effect to be compensated is a function of temperature. However, fabrication of main transistor 20 and reference transistor 70 on the same substrate is not a limitation.

As further shown in FIG. 2, operational amplifier 80 has an inverting input 82, a non-inverting input 84 and an output 86. The non-inverting input 84 of operational amplifier 80 is coupled to the source terminal 76 of reference transistor 70, and the inverting input 82 of operational amplifier receives a reference voltage. The reference voltage may be a fixed reference voltage or may be adjustable. The output 86 of operational amplifier 80 is coupled through a resistor 90 to the gate terminal 22 of main transistor 20 and is coupled through a resistor 92 to the gate terminal 72 of reference transistor 70. The drain terminal 74 of reference transistor 70 is coupled through a voltage coupling circuit, which in the embodiment of FIG. 2 is a resistor 94, to the drain terminal 24 of main transistor 20. The source terminal 76 of reference transistor 70 is coupled through a resistor 96 to ground.

In operation, the drain lag compensation circuit 30 receives the drain voltage of main transistor 20 via input 32 and provides a compensation voltage to the gate terminal 22 of main transistor 20 via output 34. More particularly, the drain voltage on drain terminal 24 of main transistor 20 causes a current to flow through resistor 94, reference transistor 70 and resistor 96 to ground, thereby producing a voltage on source terminal 76 of reference transistor 70. The voltage on source terminal 76 of reference transistor 70 is applied to non-inverting input 84 of operational amplifier 80 and is compared with the reference voltage applied to inverting input 82 of operational amplifier 80. As noted above, the reference voltage may be fixed or adjustable. Adjustment of the reference voltage permits adjustment of the drain current of main transistor 20.

The difference, if any, between the voltages on non-inverting input 84 and inverting input 82 produces a compensation voltage on output 86 of operational amplifier 80. The compensation voltage is supplied via resistor 90 to gate terminal 22 of main transistor 20, so as to control the drain current of main transistor 20. As shown in FIG. 2, the compensation voltage is combined with the gate bias voltage at gate terminal 22 and causes a variation in the voltage applied to gate terminal 22 of main transistor 20. The compensation voltage at the output 86 of operational amplifier is also supplied through resistor 92 to gate terminal 72 of reference transistor 70 and similarly controls the drain current of reference transistor 70.

The transistor circuit 10 of FIG. 2 effectively operates as a current mirror circuit. In the current mirror circuit, the drain current of main transistor 20 and the drain current of reference transistor 70 have a fixed ratio, and variations in the drain current of one transistor cause variations in the drain current of the other transistor.

As noted above, the drain lag effect in gallium nitride transistors is a function of temperature. By thermally coupling the reference transistor 70 to main transistor 20, temperature changes affect main transistor 20 and reference transistor 70 more or less equally. The temperature changes may result from the operating environment and/or from power dissipation in main transistor 20.

The transistor circuit 10 may operate in a quiescent condition with DC voltage applied to the circuit but no RF input. In the quiescent operating condition, the drain lag compensation circuit 30 compensates for temperature variations in the operating environment. In an operating condition with an RF input applied to main transistor 20, the drain lag compensation circuit 30 compensates for drain lag effects produced by the RF input. The drain lag compensation circuit 32 may operate at a speed that corresponds to the rate of the modulation of the RF input signal.

The drain lag compensation circuit 30 is described herein as compensating for drain lag which results from the trapping effect. The trapping effect is also known to produce gate lag, and the compensation circuit 30 also compensates, at least partially, for gate lag.

In one example of the transistor circuit 10, the main transistor 20 is a gallium nitride HEMT, the reference transistor 70 is a gallium nitride HEMT, resistor 90 has a value of 500 ohms, resistor 92 has a value of 1 K ohms, resistor 94 has a value of 5 K ohms, and resistor 96 has a value of 10 ohms. The transistor 20 may be an 8 mm gate periphery gallium nitride FET, and transistor 70 may be a scaled down 0.4 mm gallium nitride FET. It will be understood that these values are given by way of example only and are not limiting.

In the embodiment of FIG. 2, the sensing circuit 80 is an operational amplifier or other differential amplifier. In other embodiments, the sensing circuit can be a discrete transistor differential amplifier or a digital sensing circuit. Other sensing circuits may utilize a diode detector and/or filtering of the sensed signal.

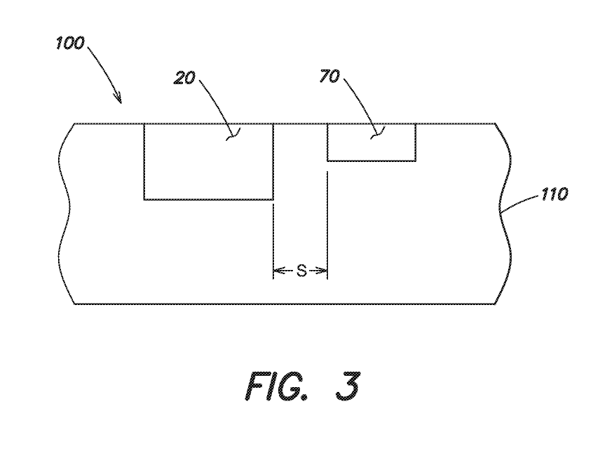

A simplified cross-sectional diagram of a semiconductor device is shown in FIG. 3. A semiconductor device 100 includes main transistor 20 and reference transistor 70 fabricated on a single substrate 110. Other components of the transistor circuit 10 shown in FIG. 2 and described above may be fabricated on substrate 110 or may be fabricated separately. A spacing S between main transistor 20 and reference transistor 70 may be selected to achieve thermal coupling between main transistor 20 and reference transistor 70, such that the temperatures of the two devices are equal or nearly equal during operation of the transistor circuit 10. It will be understood that fabrication of main transistor 20 and reference transistor 70 on a single substrate is described by way of example and is not a limitation.

Having described several embodiments of the techniques described herein in detail, various modifications, and improvements will readily occur to those skilled in the art. Such modifications and improvements are intended to be within the spirit and scope of the disclosure. Accordingly, the foregoing description is by way of example only, and is not intended as limiting. The techniques are limited only as defined by the following claims and the equivalents thereto.

What is claimed is:

1. A transistor circuit comprising:
a main transistor having a gate terminal, a drain terminal and a source terminal; and
a drain lag compensation circuit configured to sense a drain voltage on the drain terminal of the main transistor and to control a drain current through the main transistor based on the sensed drain voltage.

2. The transistor circuit as defined in claim 1, wherein the main transistor comprises a gallium nitride RF power transistor.

3. The transistor circuit as defined in claim 2, wherein the drain lag compensation circuit comprises:
a reference transistor having a drain terminal coupled to the drain terminal of the main transistor and having a source terminal coupled through a first resistor to ground; and
a sensing circuit having a first input coupled to the source terminal of the reference transistor, a second input that receives a reference value, and an output coupled to the gate terminal of the main transistor and to the gate terminal of the reference transistor.

4. The transistor circuit as defined in claim 3, wherein the reference transistor is thermally coupled to the main transistor.

5. The transistor circuit as defined in claim 3, wherein the sensing circuit is configured to compare the voltage on the source terminal of the reference transistor with the reference value and to provide a compensation voltage to the gate terminals of the main transistor and the reference transistor based on the comparison.

6. The transistor circuit as defined in claim 1, wherein the drain lag compensation circuit is configured to control the main transistor to maintain a constant quiescent drain current through the main transistor.

7. A method for operating a main transistor comprising:
sensing a drain voltage on a drain terminal of the main transistor; and
controlling a drain current through the main transistor based on the sensed drain voltage.

8. The method for operating a main transistor as defined in claim 7, wherein the main transistor is a gallium nitride RF power transistor.

9. The method for operating a main transistor as defined in claim 8, wherein sensing the drain voltage on the drain terminal of the main transistor is performed by a reference transistor having a drain terminal coupled to the drain terminal of the main transistor.

10. The method for operating a main transistor as defined in claim 9, wherein the reference transistor is thermally coupled to the main transistor.

11. The method for operating a main transistor as defined in claim 10, wherein controlling the main transistor comprises comparing a value representative of the sensed drain voltage with a reference value and providing a compensation value to a gate terminal of the main transistor based on the comparison.

12. The method for operating a main transistor as defined in claim 11, further comprising adjusting the reference value to thereby adjust the current through the main transistor.

13. The method for operating a main transistor as defined in claim 7, wherein controlling the drain current comprises maintaining a constant quiescent drain current through the main transistor.

14. A transistor circuit comprising:
a main transistor having a gate terminal, a drain terminal and a source terminal;
a reference transistor having a drain terminal coupled to the drain terminal of the main transistor and having a source terminal coupled through a first resistor to ground; and
a sensing circuit having a first input coupled to the source terminal of the reference transistor, a second input that receives a reference value, and an output coupled to a gate terminal of the main transistor and to a gate terminal of the reference transistor.

15. The transistor circuit as defined in claim 14, wherein the main transistor comprises a gallium nitride RF power transistor.

16. The transistor circuit as defined in claim 15, wherein reference transistor is thermally coupled to the main transistor.

17. The transistor circuit as defined in claim 16, wherein the sensing circuit is configured to compare a voltage on the source terminal of the reference transistor with the reference value and to provide a compensation voltage to the gate terminals of the main transistor and the reference transistor based on the comparison.

18. The transistor circuit as defined in claim 17, wherein the reference transistor is configured to sense a drain voltage on the drain terminal of the main transistor.

19. The transistor circuit as defined in claim 18, further comprising a second resistor coupled between the output of the sensing circuit and the gate terminal of the main transistor and a third resistor coupled between the output of the sensing circuit and the gate terminal of the reference transistor.

20. The transistor circuit as defined in claim 14, wherein the sensing circuit comprises an operational amplifier, the first input of the sensing circuit comprises a non-inverting input of the operational amplifier and the second input of the sensing circuit comprises an inverting input of the operational amplifier.

21. The transistor circuit as defined in claim 14, wherein the main transistor and the reference transistor are fabricated on a single substrate.
